(19) United States
(12) Patent Application Publication
(10) Pub. No.: US 2026/0116663 A1
(43) Pub. Date: Apr. 30, 2026

(54) CIRCULATION CLEANING DEVICE AND CONTROL METHOD THEREOF

(71) Applicant: Mu-tech Precision Co., Ltd., Kaohsiung City (TW)

(72) Inventors: Chih-Jen YANG, Taichung City (TW); Kuo-Chang SHIH, Pingtung County (TW); Fan-Ching CHANG, Taichung City (TW)

(73) Assignee: Mu-tech Precision Co., Ltd., Kaohsiung City (TW)

(21) Appl. No.: 19/241,633

(22) Filed: Jun. 18, 2025

(30) Foreign Application Priority Data
Oct. 24, 2024 (TW) 113140642

(51) Int. Cl. B65G 1/10; B08B 3/02; B08B 3/04; B08B 3/08; F26B 15/00; F26B 21/00

(52) U.S. Cl. CPC B65G 1/10; B08B 3/022; B08B 3/041; B08B 3/08; F26B 15/00; F26B 21/50; B08B 2203/0217; B65G 2201/0297

(57) ABSTRACT

A circulation cleaning device includes a base unit, a carrier unit juxtaposed with the base unit in a conveying direction, a cleaning unit juxtaposed with the carrier unit in the conveying direction, a direction-changing unit juxtaposed with the cleaning device in the conveying direction, and a drying unit disposed between the carrier unit and the direction-changing unit in the conveying direction and juxtaposed with the cleaning device in a transverse direction. A control method of the circulation cleaning device is provided to clean and dry a boat in circulation by moving the boat sequentially through the base unit, the carrier unit, the cleaning unit, the direction-changing unit, the drying unit and back to the base unit.

### CROSS-REFERENCE TO RELATED APPLICATION

This application claims priority to Taiwanese Invention Patent Application No. 113140642, filed on Oct. 24, 2024, the entire disclosure of which is incorporated by reference herein.

### FIELD

The disclosure relates to a cleaning device, and more particularly to a circulation cleaning device and a control method thereof.

### BACKGROUND

Recently, as semiconductor wafer processing becomes increasingly precise and the demand for semiconductor wafers is significantly increased, it is important to increase production of the semiconductor wafers while maintaining the quality of the semiconductor wafers. Currently, the semiconductor wafers and carriers of the semiconductor wafers are manually cleaned, which is labor intensive and time consuming.

Therefore, there is a need to develop an automatic cleaning device to reduce overall costs.

### SUMMARY

Therefore, an object of the disclosure is to provide a circulation cleaning device that can alleviate at least one of the drawbacks of the prior art.

According to one aspect of the disclosure, a circulation cleaning device is adapted for cleaning at least one boat that is disposed in a magazine, and includes a base unit, a carrier unit, a cleaning unit, a direction-changing unit, and a drying unit.

The carrier unit is juxtaposed with the base unit in a conveying direction and includes a carrier guide rail, a front carrier seat and a rear carrier seat that are mounted on the carrier guide rail and that are movable along the carrier guide rail in a transverse direction perpendicular to the conveying direction. The base unit is operable for conveying the at least one boat to the front carrier seat.

The cleaning unit is juxtaposed with the carrier unit in the conveying direction. The front carrier seat is operable for conveying the at least one boat from the base unit to the cleaning unit. The cleaning unit is operable for conveying the at least one boat away from the carrier unit and for cleaning the at least one boat.

The direction-changing unit is juxtaposed with the cleaning unit in the conveying direction, and includes a direction-changing guide rail and at least one direction-changing seat. The at least one direction-changing seat is mounted on the direction-changing guide rail, and is movable in the transverse direction along the direction-changing member. The direction-changing unit is operable for conveying the at least one boat on the cleaning unit to move away from the cleaning unit in the transverse direction, and then further conveying the at least one boat in the conveying direction (D2) toward the carrier unit.

The drying unit is disposed between the carrier unit and the direction-changing unit in the conveying direction, and is juxtaposed with the cleaning unit in the transverse direction. The drying unit is operable for conveying the at least one boat from the direction-changing unit toward the carrier unit and for drying the at least boat.

Another object of the disclosure is to provide a method for controlling a circulation cleaning device.

According to another aspect of the disclosure, a method for controlling a circulation cleaning device includes steps of:
(A) providing a circulation cleaning device adapted for cleaning a plurality of boats disposed in a magazine, the circulation cleaning device including a base unit, a carrier unit that is juxtaposed with the base unit in a conveying direction, a cleaning unit that is juxtaposed with the carrier unit in the conveying direction, a direction-changing unit that is juxtaposed with the cleaning unit in the conveying direction, and a drying unit that is disposed between the carrier unit and the direction-changing unit in the conveying direction, and that is juxtaposed with the cleaning unit in a transverse direction perpendicular to the conveying direction, the base unit including a lifting guide rail, a lifting seat and a pushing module, the lifting seat being mounted on the lifting rail, being movable along the lifting rail in a top-bottom direction perpendicular to the conveying direction and the transverse direction, and being adapted for receiving the magazine, the pushing module being disposed at one side of the lifting seat opposite to the carrier unit, the carrier unit including a carrier guide rail, and a front carrier seat and a rear carrier seat that are mounted on the carrier guide rail and that are movable along the carrier guide rail in a transverse direction;
(B) operating the base unit to convey the boats sequentially from the magazine to the front carrier seat of the carrier unit, such that the boats are subsequently conveyed through the cleaning unit and the direction-changing unit into the drying unit;
(C) when any one of the boats arrives at the drying unit, driving the rear carrier seat to move in the transverse direction to be adjacent to the drying unit and to receive the one of the boats from the drying unit;
(D) driving the front carrier seat to move in the transverse direction to be adjacent to the cleaning unit, and driving the front carrier seat to execute an operation of conveying one of the boats carried by the front carrier seat to the cleaning unit;
(E) driving the rear carrier seat to move in the transverse direction to be adjacent to the base unit, and driving the rear carrier seat to execute an operation of conveying the one of the boats carried by the rear carrier seat to the magazine;
(F) driving the lifting seat and the magazine to move in the top-bottom direction along the lifting rail such that another boat disposed in the magazine is moved to be level with the front carrier seat; and
(G) driving the front carrier seat to move in the transverse direction and to be adjacent to the base unit, and driving the base unit to execute an operation of conveying the another boat to the front carrier seat.

Still another object of the disclosure is to provide a method for controlling a circulation cleaning device.

According to still another aspect of the disclosure, a method for controlling a circulation cleaning device includes steps of:
(A) providing a circulation cleaning device adapted for cleaning a plurality of boats disposed in a magazine, the circulation cleaning device including a base unit, a carrier unit that is juxtaposed with the base unit in a conveying direction, a cleaning unit that is juxtaposed with the carrier unit in the conveying direction, a direction-changing unit that is juxtaposed with the cleaning unit in the conveying direction, and a drying unit that is disposed between the carrier unit and the direction-changing unit in the conveying direction, and that is juxtaposed with the cleaning unit in a transverse direction perpendicular to the conveying direction, the base unit including a lifting guide rail, a lifting seat and a pushing module, the lifting seat being mounted on the lifting rail, being movable along the lifting rail in a top-bottom direction perpendicular to the conveying direction and the transverse direction, and being adapted for receiving the magazine, the pushing module being disposed at one side of the lifting seat opposite to the carrier unit, the carrier unit including a carrier guide rail, and a front carrier seat and a rear carrier seat that are mounted on the carrier guide rail and that are movable along the carrier guide rail in a transverse direction;
(B) operating the base unit to convey the boats sequentially from the magazine to the front carrier seat of the carrier unit, such that the boats are subsequently conveyed through the cleaning unit and the direction-changing unit into the drying unit;
(C) when any one of the boats arrives at the drying unit, driving the rear carrier seat to move in the transverse direction to be adjacent to the drying unit (5) and receive the one of the boats from the drying unit;
(D) driving the front carrier seat to move in the transverse direction to be adjacent to the cleaning unit, and driving the front carrier seat to execute an operation of conveying one of the boats carried by the front carrier seat to the cleaning unit;
(E′) driving the front carrier seat to move in the transverse direction to be adjacent to the base unit (1), and driving the base unit to execute an operation of conveying another one of the boats to the front carrier seat (22).
(F) driving the lifting seat and the magazine to move in the top-bottom direction along the lifting rail; and
(G′) driving the rear carrier seat to move in the transverse direction to be adjacent to the base unit, and driving the rear carrier seat to execute an operation of conveying the one of the boats carried by the rear carrier seat to the magazine.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a block diagram illustrating a control unit signally connected to a base unit, a carrier unit, a cleaning unit, a direction-changing unit, and a drying unit of a circulation cleaning device according to an embodiment of the disclosure.

FIG. 2 is a perspective view of the embodiment illustrating the carrier unit, the cleaning unit, and the direction-changing unit.

FIG. 3 is a schematic top sectional view of the embodiment illustrating the circulation cleaning device, a magazine, and a boat.

FIG. 4 is a perspective view of the embodiment illustrating the base unit, the carrier unit, the magazine, and the boat.

FIG. 5 is a schematic top sectional view of the embodiment illustrating the base unit, the carrier unit, the magazine, and the boat.

FIG. 6 is a fragmentary perspective view of the embodiment illustrating the cleaning unit, the direction-changing unit, and the drying unit.

FIG. 7 is a schematic top sectional view of the embodiment illustrating the cleaning unit, the direction-changing unit, and the drying unit.

FIG. 8 is a schematic top sectional view of the embodiment illustrating the circulation cleaning device for cleaning boats in the magazine.

FIG. 9 illustrates a flow chart of a first method for controlling the circulation cleaning device of the disclosure.

FIG. 10 illustrates a flow chart of a second method for controlling the circulation cleaning device of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

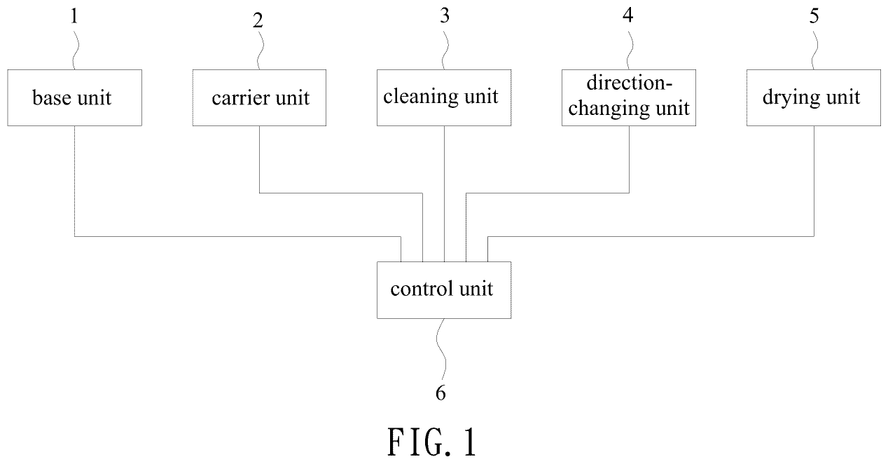

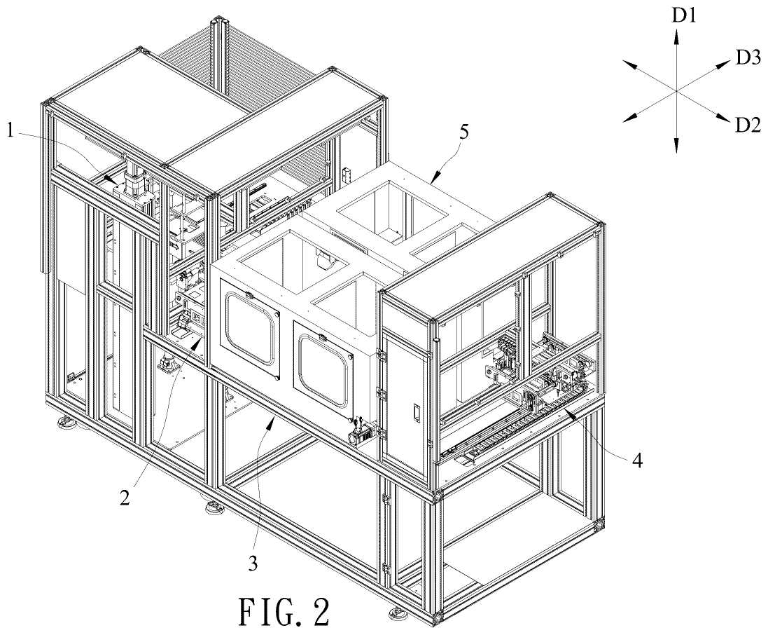

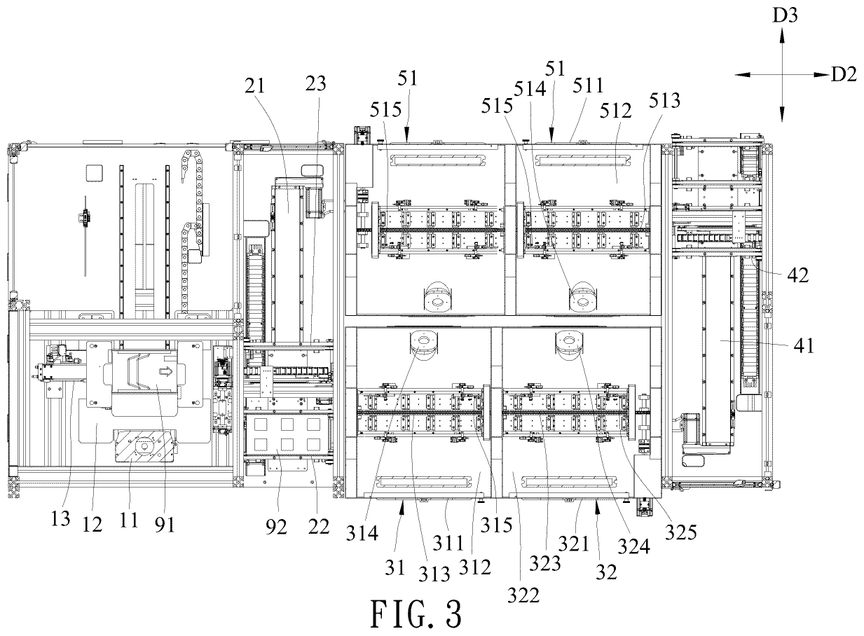

FIGS. 1, 2, and 3, illustrate a circulation cleaning device according to an embodiment of the disclosure adapted for cleaning a plurality of boats 92 that are disposed in a magazine 91. For the sake of brevity, only one of the boats 92 is exemplified below.

The circulation cleaning device of the disclosure includes a base unit 1, a carrier unit 2, a cleaning unit 3, a direction-changing unit 4, a drying unit 5, and a control unit 6 signally connected to the base unit 1, the carrier unit 2, the cleaning unit 3, the direction-changing unit 4, and the drying unit 5.

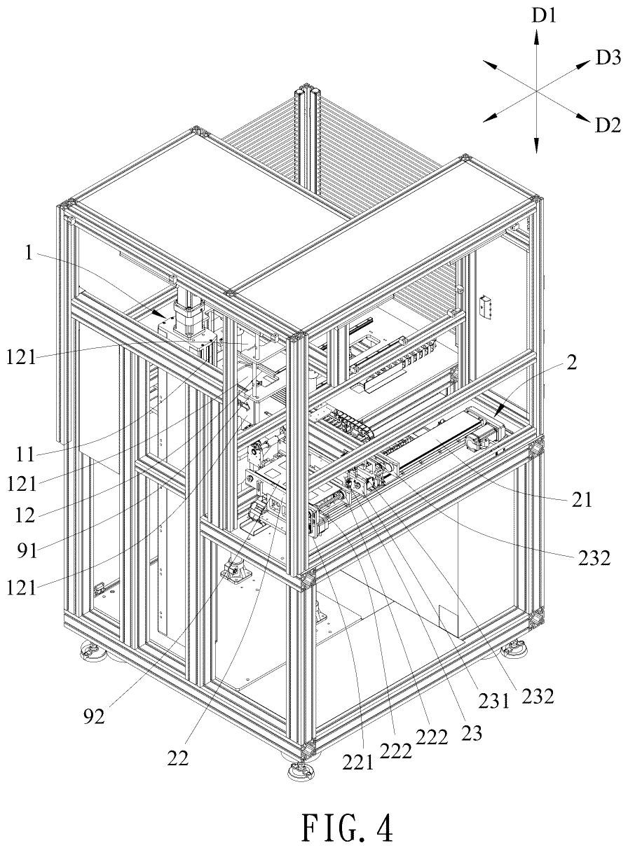

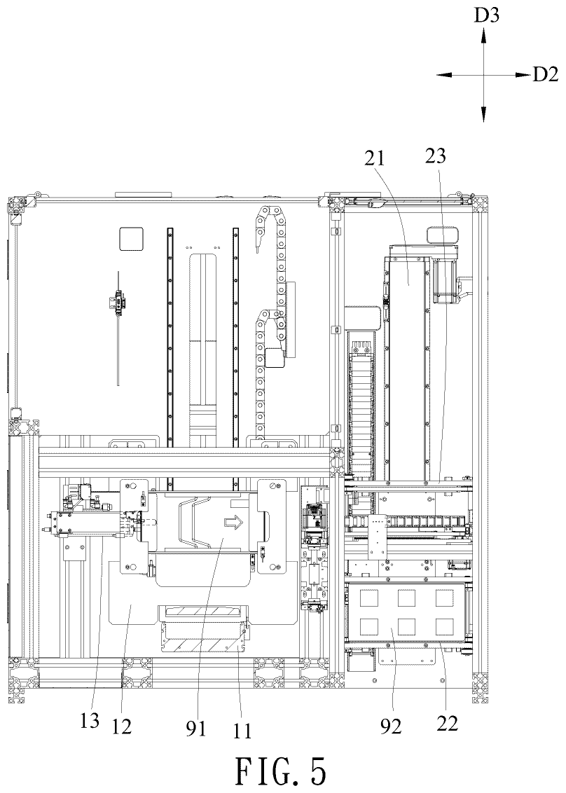

Referring to FIGS. 4 and 5, the base unit 1 includes a lifting guide rail 11, a lifting seat 12, and a pushing module 13. The lifting seat 12 is mounted on the lifting rail 11, and is movable along the lifting rail 11 in a top-bottom direction (D1). The pushing module 13 is disposed at one side of the lifting seat 12 opposite to the carrier unit 2. In this embodiment, the lifting seat has a plurality of magazine spaces 121. Two adjacent ones of the magazine spaces 121 are disposed in the top-bottom direction (D1) relative to each other. Each of the magazine spaces 121 is adapted for receiving a magazine 91. That is to say, the lifting seat 12 may receive a plurality of magazines 91.

The carrier unit 2 is juxtaposed with the base unit 1 in a conveying direction (D2) perpendicular to the top-bottom direction (D1), and includes a carrier guide rail 21, a front carrier seat 22, and a rear carrier seat 23. The front carrier seat 22 and the rear carrier seat 23 are mounted on the carrier guide rail 21 and are movable along the carrier guide rail 21 in a transverse direction (D3) perpendicular to the top-bottom direction (D1) and the conveying direction (D2). In this embodiment, the base unit 1 is operable for conveying the boat 92 to the front carrier seat 22. The conveying direction (D2) is a left-right direction.

The front carrier seat 22 has a front seat body 221 and two front conveyor belts 222. The two front conveyor belts 222 are rotatably and respectively disposed on two opposite sides of the front seat body 221. The pushing module 13 is adapted for pushing the boat 92 to the front carrier seat 22. The two front conveyor belts 222 cooperate with each other for conveying the boat 92 from the base unit 1 to the cleaning unit 3 in the conveying direction (D2).

The rear carrier seat 23 has a rear seat body 231 and two rear conveyor belts 232. The two rear conveyor belts 232 are rotatably and respectively disposed on two opposite sides of the rear seat body 231, and cooperate with each other for conveying the boat 92 from the drying unit 5 in the conveying direction (D2), such that the boat 92 is conveyed away from the drying unit 5.

In this embodiment, the front carrier seat 22 and the rear carrier seat 23 are co-movable with each other.

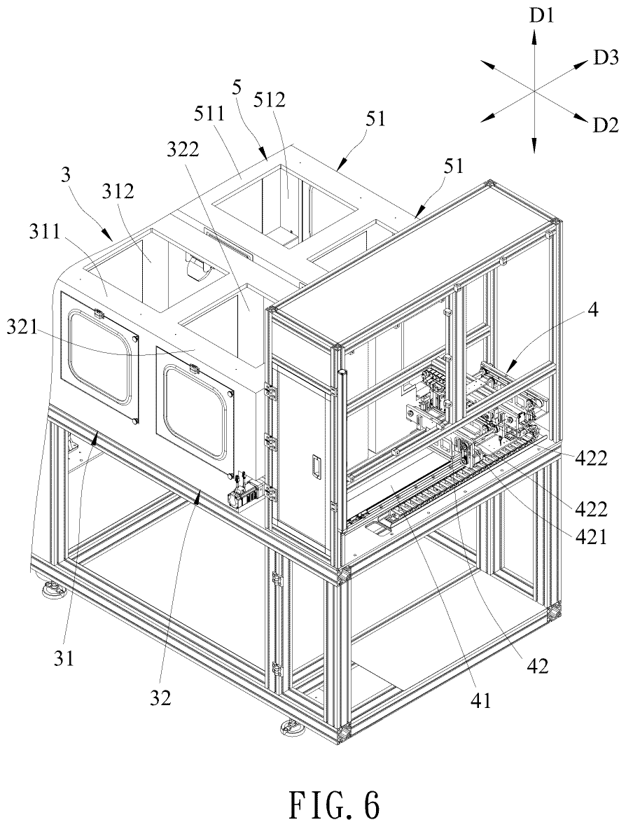

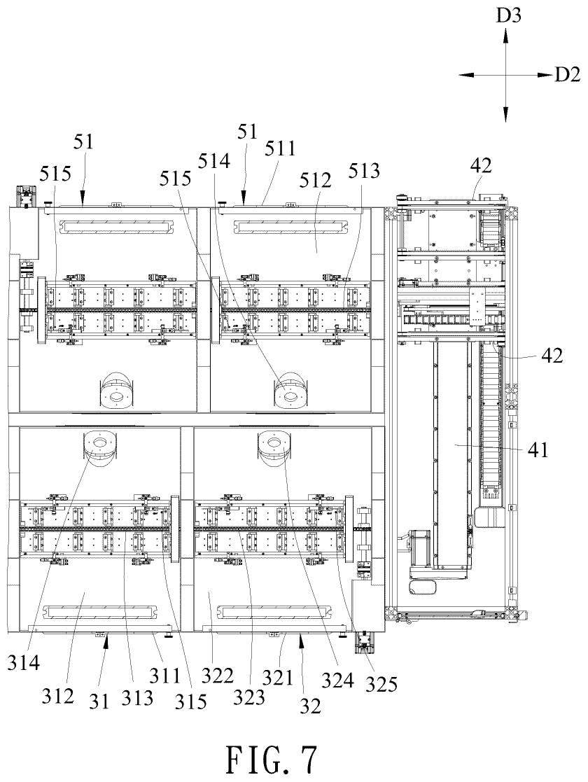

Referring to FIGS. 6 and 7, the cleaning unit 3 is juxtaposed with the carrier unit 2 in the conveying direction (D2). The front carrier seat 22 is operable for conveying the boat 92 from the base unit 1 to the cleaning unit 3. The cleaning unit 3 is operable for conveying the boat 92 away from the carrier unit 2 and for cleaning the boat 92.

The cleaning unit 3 includes a chemically cleaning module 31 that is juxtaposed with the carrier unit 2 in the conveying direction (D2), and a deionized water cleaning module 32 that is juxtaposed with the chemically cleaning module 31 in the conveying direction (D2).

The chemically cleaning module 31 has a first cleaning housing 311, a first conveyor belt 313, a first cleaning nozzle 314, and a first sensor 315. The first cleaning housing 311 defines a first cleaning space 312. The first conveyor belt 313 is disposed in the first cleaning space 312 and is adapted for moving the boat 92 in the conveying direction (D2). The first cleaning nozzle 314 is disposed in the first cleaning space 312 and is adapted for spraying a chemical solution to the boat 92. The first sensor 315 is adjacent to the first conveyor belt 313, and is signally connected to the control unit 6. In this embodiment, the first sensor 315 is an infrared detector.

In other embodiments, a quantity of the first cleaning nozzle 314 may be greater than one.

The deionized water cleaning module 32 has a second cleaning housing 321, a second conveyor belt 323, a second cleaning nozzle 324, and a second sensor 325. The second cleaning housing 321 defines a second cleaning space 322. The second conveyor belt 323 is disposed in the second cleaning space 322 and is adapted for moving the boat 92 emerging from the chemically cleaning module 31 in the conveying direction (D2). The second cleaning nozzle 324 is disposed in the second cleaning space 322 and is adapted for spraying deionized water to the boat 92. The second sensor 325 is adjacent to the second conveyor belt 323, and is signally connected to the control unit 6. In this embodiment, the second sensor 325 is an infrared detector.

In other embodiments, a quantity of the second cleaning nozzle 324 may be greater than one.

Specifically, in this embodiment, each of the first conveyor belt 313 and the second conveyor belt 323 is a chain conveyor belt. In other embodiments, the first conveyor belt 313 and the second conveyor belt 323 may be formed together as a chain conveyor belt, or may be other different types of conveyor belts.

The direction-changing unit 4 is juxtaposed with the cleaning unit 3 in the conveying direction (D2), and includes a direction-changing guide rail 41 and two direction-changing seats 42. The two direction-changing seats 42 are mounted on the direction-changing guide rail 41 and are movable along the direction-changing guide rail 41 in the transverse direction (D3). The direction-changing unit 4 is operable such that one of the direction-changing seats 42 is adapted for conveying the boat 92 on the cleaning unit 3 to move away from the cleaning unit 3 in the transverse direction (D3), and then further conveying the boat 92 in the conveying direction (D2) toward the carrier unit 2. Each of the direction-changing seats 42 has a direction-changing seat body 421, and two direction-changing conveyor belts 422 that are respectively and rotatably disposed on two sides of the direction-changing seat body 421. In other embodiments, the direction-changing unit 4 may include only one direction-changing seat 42 for conveying the boat 92 on the cleaning unit 3 to move away from the cleaning unit 3 in the transverse direction (D3). The reason for the direction-changing unit 4 in this embodiment including two direction-changing seats 42 is that the direction-changing unit 4 is designed to be the same as the carrier unit 2, so as to save the cost of designing the direction-changing unit 4.

The drying unit 5 is disposed between the carrier unit 2 and the direction-changing unit 4 in the conveying direction (D2), and is juxtaposed with the cleaning unit 3 in the transverse direction (D3). The drying unit 5 is operable for conveying the boat 92 from the direction-changing unit 4 toward the carrier unit 2 and for drying the boat 92.

The drying unit 5 includes two air-drying modules 51 that are juxtaposed with each other in the conveying direction (D2). Each of the two air-drying modules 51 has an air-drying housing 511, an air-drying conveyor belt 513, an air-drying nozzle 514, and a third sensor 515. The air-drying housing 511 defines an air-drying space 512. The air-drying conveyor belt 513 is disposed in the air-drying space 512 and is adapted for moving the boat 92 in the conveying direction (D2) toward the carrier unit 2. The air-drying nozzle 514 is disposed in the air-drying space 512 and is adapted for air-drying the boat 92. The third sensor 515 is adjacent to the air-drying conveyor belt 513, and is signally connected to the control unit 6. In this embodiment, the third sensor 515 is an infrared detector.

In other embodiments, a quantity of the air-drying nozzle 514 may be greater than one.

It should be noted that the two direction-changing conveyor belts 422 are both chain conveyor belts and are spaced apart from each other. However, in some embodiments, the two direction-changing conveyor belts 422 may be formed together as a chain conveyor belt.

In this embodiment, the control unit 6 may consist of a processor (not shown) and a computer-readable medium (not shown) that is electrically connected to the processor and that stores a plurality of program commands. In other embodiments, the control unit 6 may be implemented by hardware or firmware such as a field-programmable gate array (FPGA), a microprocessor, or a system on chip.

In a conventional cleaning device in contrast to the circulation cleaning device of the disclosure, the base unit may only feed materials, and the cleaning unit and the drying unit are sequentially arranged in the conveying direction without a change in direction. Without the direction-changing unit, the conventional cleaning device may be required to include another base unit for receiving a boat that is conveyed from the drying unit for discharging the materials, thereby causing the conventional cleaning device to be long and narrow in appearance such that the conventional cleaning device may occupy the factory space unevenly.

In the circulation cleaning device of the disclosure, by virtue of the base unit 1, the carrier unit 2 juxtaposed with the base unit 1 in the conveying direction (D2), the cleaning unit 3 juxtaposed with the carrier unit 2 in the conveying direction (D2), the direction-changing unit 4 juxtaposed with the cleaning unit 3 in the conveying direction (D2), and the drying unit 5 disposed between the carrier unit 2 and the direction-changing unit 4 in the conveying direction (D2), and juxtaposed with the cleaning unit 3 in the transverse direction (D3), the circulation cleaning device of the disclosure is not long and narrow in appearance, so the circulation cleaning device of the disclosure does not occupy the factory space unevenly, and the boats 92 that are cleaned and dried may be returned to the base unit 1 easily.

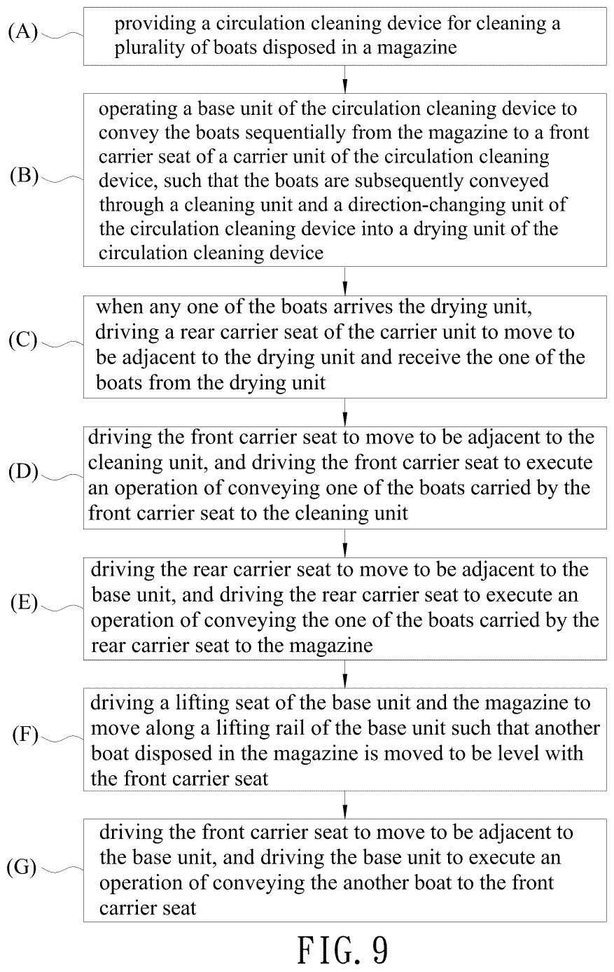

Referring to FIGS. 1, 8, and 9, each of the boats 92 is moved sequentially through the front carrier seat 22, the first cleaning housing 311, the second cleaning housing 321, one of the direction-changing seats 42, and the air-drying housings 511 of the two air-drying modules 51, such that the boats 92 are automatically cleaned and dried. A first method for controlling a circulation cleaning device of the disclosure includes the following steps.

In step (A), a circulation cleaning device of the disclosure is provided and adapted for cleaning a plurality of boats 92 disposed in a magazine 91. The circulation cleaning device includes a base unit 1, a carrier unit 2 that is juxtaposed with the base unit 1 in a conveying direction (D2), a cleaning unit 3 that is juxtaposed with the carrier unit 2 in the conveying direction (D2), a direction-changing unit 4 that is juxtaposed with the cleaning unit 3 in the conveying direction (D2), a drying unit 5 that is disposed between the carrier unit 2 and the direction-changing unit 4 in the conveying direction (D2), and that is juxtaposed with the cleaning unit 3 in a transverse direction (D3) perpendicular to the conveying direction (D2), and a control unit 6 signally connected to the base unit 1, the carrier unit 2, the cleaning unit 3, the direction-changing unit 4, and the drying unit 5. The base unit 1 includes a lifting guide rail 11, a lifting seat 12 and a pushing module 13. The lifting seat 12 is mounted on the lifting rail 11, is movable along the lifting rail 11 in a top-bottom direction (D1) perpendicular to the conveying direction (D2) and the transverse direction (D3), and is adapted for receiving the magazine 91. The pushing module 13 is disposed at one side of the lifting seat 12 opposite to the carrier unit 2. The carrier unit 2 includes a carrier guide rail 21, and a front carrier seat 22 and a rear carrier seat 23 that are mounted on the carrier guide rail 21 and that are movable along the carrier guide rail 21 in the transverse direction (D3).

In step (B), the base unit 1 is operated through the control unit 6 to convey the boats 92 sequentially from the magazine 91 to the front carrier seat 22 of the carrier unit 2, such that the boats 92 are subsequently conveyed through the cleaning unit 3 and the direction-changing unit 4 into the drying unit 5. The step (B) includes step (1), step (B-2), step (B-3), and step (B-4).

In step (B-1), through the control unit 6, the lifting seat 12 and the magazine 91 are driven to move in the top-bottom direction (D1) along the lifting rail 11 such that one of the boats 92 disposed in the magazine 91 is aligned with the pushing module 13, and the pushing module 13 is driven to push the one of the boats 92 to the front carrier seat 22. Specifically, it may take about 5 seconds to 10 seconds to move the lifting seat 12 and the magazine 91.

In step (B-2), through the control unit 6, when the chemically cleaning module 31 receives none of the boats 92, the front carrier seat 22 is driven to move in the transverse direction (D3) to be adjacent to the cleaning unit 3, and the front carrier seat 22 is driven to execute an operation of conveying the one of the boats 92 to the cleaning unit 3. In this embodiment, when the first sensor 315 of the chemically cleaning module 31 detects the chemically cleaning module 31 without the boats 92 and transmits an idle signal to the control unit 6, the control unit 6 may recognize that the chemically cleaning module 31 is in an idle state, thereby driving the front carrier seat 22 to convey the one of the boats 92 to the cleaning unit 3.

In step (B-3), through the control unit 6, the front carrier seat 22 is driven to move in the transverse direction (D3) to be adjacent to the base unit 1, the lifting seat 12 and the magazine 91 are driven to move in the top-bottom direction (D1) along the lifting rail 11 such that another one of the boats 92 is aligned with the pushing module 13, and the pushing module 13 is driven to push the another one of the boats 92 to the front carrier seat 22.

In step (B-4), through the control unit 6, step (B-1), step (B-2), and step (B-3) are repeated until the drying unit 5 receives any one of the boats 92. Specifically, it may take about 5 seconds to 10 seconds to move the front carrier seat 22 in the transverse direction (D3) from step (B-2) to step (B-3).

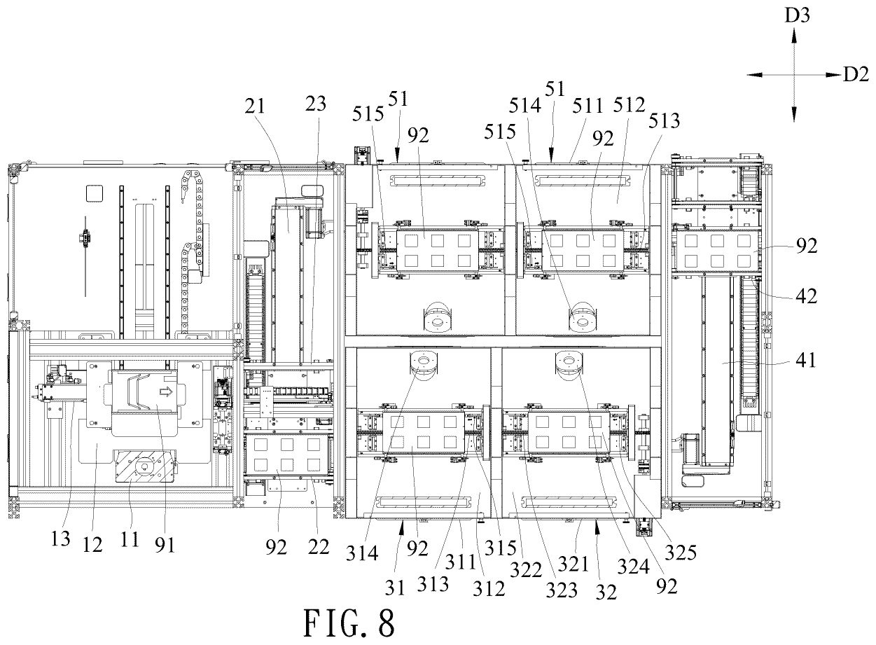

In this embodiment, each of the boats 92 stays in the front carrier seat 22 for about 5 seconds to 10 seconds. Each of the boats 92 stays in the first cleaning housing 311 for about 45 seconds to 120 seconds. Each of the boats 92 stays in the second cleaning housing 321 for about 45 seconds to 120 seconds. Each of the boats 92 stays in one of the direction-changing seats 42 for about 5 seconds to 10 seconds. Each of the boats 92 stays in the air-drying housing 511 of a corresponding one of the two air-drying modules 51 for about 40 seconds to 115 seconds. For ease of description, as shown in FIG. 8, six of the boats 92 are exemplified to be sequentially conveyed through the front carrier seat 22 of the carrier unit 2, the first cleaning housing 311, the second cleaning housing 321, one of the direction-changing seats 42, and the air-drying housings 511 of the two air-drying modules 51. As aforementioned, each of the boats 92 stays in the first cleaning housing 311, the second cleaning housing 321, and the air-drying housing 511 of a corresponding one of the two air-drying modules 51 for a relatively long period. Each of the boats 92 stays in the air-drying housing 511 of a corresponding one of the two air-drying modules 51 for 5 seconds less than the time that each of the boats 92 stays in the first cleaning housing 311 or the second cleaning housing 321. When any one of the boats 92 stays in and is dried by one of two air-drying modules 51 adjacent to the carrier guide rail 21, the carrier seat 23 of the carrier unit 2 is moved at once to carry the dried boat 92 away from the one of two air-drying modules 51 adjacent to the carrier guide rail 21.

In step (C), through the control unit 6, when any one of the boats 92 arrives at the one of two air-drying modules 51 of the drying unit 5 adjacent to the carrier guide rail 21, the rear carrier seat 23 is driven to move in the transverse direction (D3) to be adjacent to the drying unit 5 and to receive the one of the boats 92 from the drying unit 5. In this embodiment, when the third sensor 515 of the one of two air-drying modules 51 adjacent to the carrier guide rail 21 detects the one of two air-drying modules 51 adjacent to the carrier guide rail 21 receives any one of the boats 92 and transmits a triggering signal to the control unit 6, the control unit 6 may recognize that the one of two air-drying modules 51 adjacent to the carrier guide rail 21 receives any one of the boats 92. The control unit 6 may wait for a predetermined period after receiving the triggering signal and then drives the rear carrier seat 23 to move in the transverse direction (D3) to be adjacent to the drying unit 5 and to receive the one of the boats 92 from the drying unit 5. The predetermined period for which the control unit 6 waits corresponds to the time that each of the boats 92 stays in the air-drying housing 511 of the corresponding one of the two air-drying modules 51 so that the rear carrier seat 23 may immediately receive the one of the boats 92 from the drying unit 5.

In step (D), through the control unit 6, the front carrier seat 22 is driven to move in the transverse direction (D3) to be adjacent to the cleaning unit 3, and the front carrier seat 22 is driven to execute an operation of conveying one of the boats 92 carried by the front carrier seat 22 to the cleaning unit 3.

In step (E), through the control unit 6, the rear carrier seat 23 is driven to move in the transverse direction (D3) to be adjacent to the base unit 1, and the rear carrier seat 23 is driven to execute an operation of conveying the one of the boats 92 carried by the rear carrier seat 23 to the magazine 91.

In step (F), through the control unit6, the lifting seat 12 and the magazine 91 are driven to move in the top-bottom direction (D1) along the lifting rail 11 such that another one of the boats 92 disposed in the magazine 91 is moved to be level with the front carrier seat 22.

In step (G), through the control unit 6, the front carrier seat 22 is driven to move in the transverse direction (D3) and to be adjacent to the base unit 1, and the base unit 1 is driven to execute an operation of conveying the another one of the boats 92 from the magazine 91 to the front carrier seat 22.

Specifically, in each of the steps (A) to (G), the front carrier seat 22 and the rear carrier seat 23 are co-movable with each other.

In another conventional cleaning device in contrast to the circulation cleaning device of the disclosure, the carrier unit may include only one carrier seat. The interval between the time that the carrier seat receives one of the boats from the drying unit and the time that the carrier seat conveys one of the boats thereon to the cleaning unit includes a wait time required for the carrier seat to convey the one of the boat thereon to the magazine and the wait time required for the carrier seat to receive the other one of the boats from the magazine, which is about 60 seconds on average.

In the circulation cleaning device of the disclosure, because the carrier unit 2 includes the front carrier seat 22 and the rear carrier seat 23, based on step (C) to step (D) of the first method, the wait time that the rear carrier seat 23 requires to convey the boat 92 thereon to the magazine 91 and the wait time that the front carrier 22 requires to receive another boat 92 from the magazine 91 is reduced. After the rear carrier seat 23 receives the boat 92 conveyed from the drying unit 5, the front carrier seat 22 may immediately convey the boat 92 thereon to the cleaning unit 3. As a result, the interval between the time that the rear carrier seat 23 receives one of the boats 92 from the drying unit 5 and the time that the front carrier seat 22 conveys the one of the boats 92 thereon to the cleaning unit 3 is about 15 seconds on average.

By virtue of the carrier unit 2 including the front carrier seat 22 and the rear carrier seat 23, the interval between the time that the rear carrier seat 23 receives one of the boats 92 from the drying unit 5 and the time that the front carrier seat 22 conveys one of the boats 92 thereon to the cleaning unit 3 may be significantly reduced, thereby increasing cleaning efficiency.

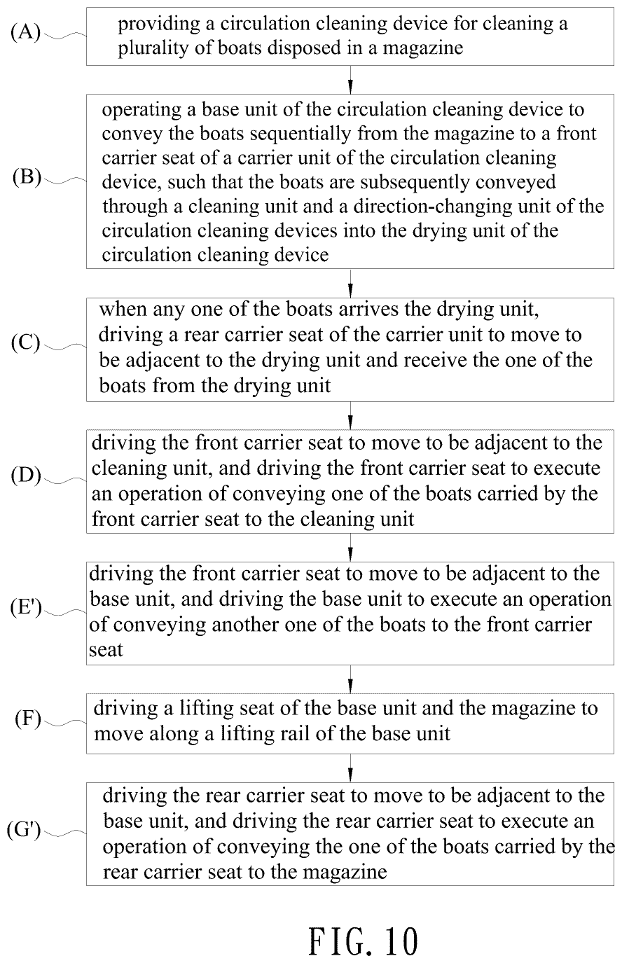

As shown in FIGS. 1, 8, and 10, a second method for controlling a circulation cleaning device of the disclosure includes the following steps.

In step (A), a circulation cleaning device of the disclosure is provided and adapted for cleaning a plurality of boats 92 disposed in a magazine 91. The circulation cleaning device includes a base unit 1, a carrier unit 2 that is juxtaposed with the base unit 1 in a conveying direction (D2), a cleaning unit 3 that is juxtaposed with the carrier unit 2 in the conveying direction (D2), a direction-changing unit 4 that is juxtaposed with the cleaning unit 3 in the conveying direction (D2), a drying unit 5 that is disposed between the carrier unit 2 and the direction-changing unit 4 in the conveying direction (D2), and that is juxtaposed with the cleaning unit 3 in a transverse direction (D3) perpendicular to the conveying direction (D2), and a control unit 6 signally connected to the base unit 1, the carrier unit 2, the cleaning unit 3, the direction-changing unit 4, and the drying unit 5. The base unit 1 includes a lifting guide rail 11, a lifting seat 12 and a pushing module 13. The lifting seat 12 is mounted on the lifting rail 11, is movable along the lifting rail 11 in a top-bottom direction (D1) perpendicular to the conveying direction (D2) and the transverse direction (D3), and is adapted for receiving the magazine 91. The pushing module 13 is disposed at one side of the lifting seat 12 opposite to the carrier unit 2. The carrier unit 2 including a carrier guide rail 21, and a front carrier seat 22 and a rear carrier seat 23 that are mounted on the carrier guide rail 21 and that are movable along the carrier guide rail 21 in the transverse direction (D3).

In step (B), through the control unit 6, the base unit 1 is operated to convey the boats 92 sequentially from the magazine 91 to the front carrier seat 22 of the carrier unit 2, such that the boats 92 are subsequently conveyed through the cleaning unit 3 and the direction-changing unit 4 into the drying unit 5. The step (B) includes step (B-1), step (B-2), step (B-3), and step (B-4).

In step (B-1), through the control unit 6, the lifting seat 12 and the magazine 91 are driven to move in the top-bottom direction (D1) along the lifting rail 11 such that one of the boats 92 disposed in the magazine 91 is aligned with the pushing module 13, and the pushing module 13 is driven to push the one of the boats 92 to the front carrier seat 22.

In step (B-2), through the control unit 6, when the chemically cleaning module 31 receives none of the boats 92, the front carrier seat 22 is driven to move in the transverse direction (D3) to be adjacent to the cleaning unit 3, and the front carrier seat 22 is driven to execute an operation of conveying the one of the boats 92 to the cleaning unit 3.

In step (B-3), through the control unit 6, the front carrier seat 22 is driven to move in the transverse direction (D3) to be adjacent to the base unit 1, the lifting seat 12 and the magazine 91 are driven to move in the top-bottom direction (D1) along the lifting rail 11 such that another one of the boats 92 is aligned with the pushing module 13, and the pushing module 13 is driven to push the another one of the boats 92 to the front carrier seat 22.

In step (B-4), through the control unit 6, step (B-1), step (B-2), and step (B-3) are repeated until the drying unit 5 receives any one of the boats 92.

In step (C), through the control unit 6, when any one of the boats 92 arrives at the one of two air-drying modules 51 of the drying unit 5 adjacent to the carrier guide rail 21, the rear carrier seat 23 is driven to move in the transverse direction (D3) to be adjacent to the drying unit 5 and to receive the one of the boats 92 from the drying unit 5.

In step (D), through the control unit 6, the front carrier seat 22 is driven to move in the transverse direction (D3) to be adjacent to the cleaning unit 3, and the front carrier seat 22 is driven to execute an operation of conveying one of the boats 92 carried by the front carrier seat 22 to the cleaning unit 3.

In step (E′), through the control unit 6, the front carrier seat 22 is driven to move in the transverse direction (D3) to be adjacent to the base unit 1, and the base unit 1 is driven to execute an operation of conveying another one of the boats 92 to the front carrier seat 22.

In step (F), through the control unit 6, the lifting seat 12 and the magazine 91 are driven to move in the top-bottom direction (D1) along the lifting rail 11.

In step (G′), through the control unit 6, the rear carrier seat 23 is driven to move in the transverse direction (D3) to be adjacent to the base unit 1, and the rear carrier seat 23 is driven to execute an operation of conveying the one of the boats 92 carried by the rear carrier seat 23 to the magazine 91.

Regarding the second method, in each of the steps (A) to (G′), the front carrier seat 22 and the rear carrier seat 23 are co-movable with each other.

The first and second methods for controlling the circulation cleaning device of the disclosure are different from each other in that step (E′) of the second method is interchanged with step (G) of the first method, and step (G′) of the second method is interchanged with step (E) of the first method. Because step (E′) of the second method (or step (G) of the first method) and step (G′) of the second method (or step (E) of the first method) are independent from each other, interchanging step (E′) (or step (G)) and step (G′) (or step (E)) may not adversely affect the operation of the circulation cleaning device of the disclosure.

In addition, because the carrier unit 2 includes the front carrier seat 22 and the rear carrier seat 23, based on step (C) to step (D) of the second method, the time that the rear carrier seat 23 waits to convey the boat 92 thereon to the magazine 91 and the time that the front carrier 22 waits to receive another boat 92 from the magazine 91 may be reduced.

As a result, the interval between the time that the rear carrier seat 23 receives one of the boats 92 from the drying unit 5 and the time that the front carrier seat 22 conveys one of the boats 92 thereon to the cleaning unit 3 may be reduced, thereby increasing the cleaning efficiency.

In summary, the circulation cleaning device of the disclosure and the methods for controlling the circulation cleaning device of the disclosure have the following advantages.

(1) By virtue of the base unit 1, the carrier unit 2 juxtaposed with the base unit 1 in the conveying direction (D2), the cleaning unit 3 juxtaposed with the carrier unit 2 in the conveying direction (D2), the direction-changing unit 4 juxtaposed with the cleaning unit 3 in the conveying direction (D2), and the drying unit 5 disposed between the carrier unit 2 and the direction-changing unit 4 in the conveying direction (D2), and juxtaposed with the cleaning unit 3 in the transverse direction (D3), each of the boats 92 is circulated back to the magazine 91 in the base unit 1 after being moved sequentially through the carrier unit 2, the cleaning unit 3, the direction-changing unit 4, and the drying unit 5. To achieve automatic cleaning, the circulation cleaning device of the disclosure is prevented from occupying the factory space unevenly, and the boats 92 being cleaned and dried are returned to the base unit 1 easily.

(2) Because the front carrier seat 22 and the rear carrier seat 23 are co-movable with each other, the interval between the time that the rear carrier seat 23 receives one of the boats 92 from the drying unit 5 and the time that the front carrier seat 22 conveys one of the boats 92 thereon to the cleaning unit 3 may be reduced, thereby increasing the cleaning efficiency.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A circulation cleaning device adapted for cleaning at least one boat that is disposed in a magazine, said circulation cleaning device comprising:
a base unit;
a carrier unit juxtaposed with said base unit in a conveying direction and including
a carrier guide rail, and
a front carrier seat and a rear carrier seat that are mounted on said carrier guide rail and that are movable along said carrier guide rail in a transverse direction perpendicular to the conveying direction, said base unit being operable for conveying the at least one boat to said front carrier seat;
a cleaning unit juxtaposed with said carrier unit in the conveying direction, said front carrier seat being operable for conveying the at least one boat from said base unit to said cleaning unit, said cleaning unit being operable for conveying the at least one boat away from said carrier unit and for cleaning the at least one boat;
a direction-changing unit juxtaposed with said cleaning unit in the conveying direction, and including
a direction-changing guide rail, and
at least one direction-changing seat that is mounted on said direction-changing guide rail, and that is movable in the transverse direction along said direction-changing member, said direction-changing unit being operable for conveying the at least one boat on said cleaning unit to move away from said cleaning unit in the transverse direction, and then further conveying the at least one boat in the conveying direction toward said carrier unit; and
a drying unit disposed between said carrier unit and said direction-changing unit in the conveying direction, and juxtaposed with said cleaning unit in the transverse direction, said drying unit being operable for conveying the at least one boat from said direction-changing unit toward said carrier unit and for drying the at least boat.

2. The circulation cleaning device as claimed in claim 1, wherein said base unit includes
a lifting guide rail,
a lifting seat that is mounted on said lifting rail, that is movable along said lifting rail in a top-bottom direction perpendicular to the conveying direction and the transverse direction, and that is adapted for receiving the magazine, and
a pushing module that is disposed at one side of said lifting seat opposite to said carrier unit, and that is adapted for pushing the at least one boat to said front carrier seat.

3. The circulation cleaning device as claims in claim 1, wherein:
said front carrier seat has
a front seat body, and
two front conveyor belts that are rotatably and respectively disposed on two opposite sides of said front seat body, and that cooperate with each other for conveying the at least one boat from said base unit to said cleaning unit in the conveying direction; and
said rear carrier seat has
a rear seat body, and
two rear conveyor belts that are rotatably and respectively disposed on two opposite sides of said rear seat body, and that cooperate with each other for conveying the at least one boat from said drying unit in the conveying direction.

4. The circulation cleaning device as claims in claim 1, wherein:
said cleaning unit includes
a chemically cleaning module that is juxtaposed with said carrier unit in the conveying direction, and
a deionized water cleaning module that is juxtaposed with said chemically cleaning module in the conveying direction;
said chemically cleaning module has
a first cleaning housing that defines a first cleaning space,
a first conveyor belt that is disposed in said first cleaning space and that is adapted for moving the at least one boat in the conveying direction, and
at least one first cleaning nozzle that is disposed in said first cleaning space and that is adapted for spraying a chemical solution to the at least one boat; and
said deionized water cleaning module has
a second cleaning housing that defines a second cleaning space,
a second conveyor belt that is disposed in said second cleaning space and that is adapted for moving the at least one boat emerging from said chemically cleaning module in the conveying direction, and
at least one second cleaning nozzle that is disposed in said second cleaning space and that is adapted for spraying deionized water to the at least one boat.

5. The circulation cleaning device as claims in claim 1, wherein:
said drying unit includes two air-drying modules that are juxtaposed with each other in the conveying direction; and
each of said two air-drying modules has
an air-drying housing that defines an air-drying space,
an air-drying conveyor belt that is disposed in said air-drying space and that is adapted for moving the at least one boat in the conveying direction toward said carrier unit, and
at least one air-drying nozzle that is disposed in said air-drying space and that is adapted for air-drying the at least one boat.

6. The circulation cleaning device as claims in claim 1, wherein said at least one direction-changing seat has
a direction-changing seat body, and
two direction-changing conveyor belts that are respectively and rotatably disposed on two sides of said direction-changing seat body.

7. The circulation cleaning device as claims in claim 1, wherein said front carrier seat and said rear carrier seat are co-movable with each other.

8. A method for controlling a circulation cleaning device, said method comprising steps of:
(A) providing a circulation cleaning device adapted for cleaning a plurality of boats disposed in a magazine, the circulation cleaning device including a base unit, a carrier unit that is juxtaposed with the base unit in a conveying direction, a cleaning unit that is juxtaposed with the carrier unit in the conveying direction, a direction-changing unit that is juxtaposed with the cleaning unit in the conveying direction, and a drying unit that is disposed between the carrier unit and the direction-changing unit in the conveying direction, and that is juxtaposed with the cleaning unit in a transverse direction perpendicular to the conveying direction, the base unit including a lifting guide rail, a lifting seat and a pushing module, the lifting seat being mounted on the lifting rail, being movable along the lifting rail in a top-bottom direction perpendicular to the conveying direction and the transverse direction, and being adapted for receiving the magazine, the pushing module being disposed at one side of the lifting seat opposite to the carrier unit, the carrier unit including a carrier guide rail, and a front carrier seat and a rear carrier seat that are mounted on the carrier guide rail and that are movable along the carrier guide rail in a transverse direction;
(B) operating the base unit to convey the boats sequentially from the magazine to the front carrier seat of the carrier unit, such that the boats are subsequently conveyed through the cleaning unit and the direction-changing unit into the drying unit;
(C) when any one of the boats arrives at the drying unit, driving the rear carrier seat to move in the transverse direction to be adjacent to the drying unit and to receive the one of the boats from the drying unit;
(D) driving the front carrier seat to move in the transverse direction to be adjacent to the cleaning unit, and driving the front carrier seat to execute an operation of conveying one of the boats carried by the front carrier seat to the cleaning unit;
(E) driving the rear carrier seat to move in the transverse direction to be adjacent to the base unit, and driving the rear carrier seat to execute an operation of conveying the one of the boats carried by the rear carrier seat to the magazine;
(F) driving the lifting seat and the magazine to move in the top-bottom direction along the lifting rail such that another one of the boats disposed in the magazine is moved to be level with the front carrier seat; and
(G) driving the front carrier seat to move in the transverse direction and to be adjacent to the base unit, and driving the base unit to execute an operation of conveying the another one of the boats to the front carrier seat.

9. The method for controlling the circulation cleaning device as claimed in claim 8, wherein step includes:
(B-1) driving the lifting seat and the magazine to move in the top-bottom direction along the lifting rail such that one of the boats disposed in the magazine is aligned with the pushing module, and driving the pushing module to push the one of the boats to the front carrier seat;
(B-2) driving the front carrier seat to move in the transverse direction to be adjacent to the cleaning unit, and driving the front carrier seat to execute an operation of conveying the one of the boats to the cleaning unit;
(B-3) driving the front carrier seat to move in the transverse direction to be adjacent to the base unit, driving the lifting seat and the magazine to move in the top-bottom direction along the lifting rail such that another one of the boats is aligned with the pushing module, and driving the pushing module to push the another one of the boats to the front carrier seat; and
(B-4) repeating step (B-1), step (B-2), and step (B-3) until the drying unit receives any one of the boats.

10. The method for controlling the circulation cleaning device as claimed in claim 8, wherein in each of step (A) to step (G), the front carrier seat and the rear carrier seat are co-movable with each other.

11. A method for controlling a circulation cleaning device, said method comprising steps of:
(A) providing a circulation cleaning device adapted for cleaning a plurality of boats disposed in a magazine, the circulation cleaning device including a base unit, a carrier unit that is juxtaposed with the base unit in a conveying direction, a cleaning unit that is juxtaposed with the carrier unit in the conveying direction, a direction-changing unit that is juxtaposed with the cleaning unit in the conveying direction, and a drying unit that is disposed between the carrier unit and the direction-changing unit in the conveying direction, and that is juxtaposed with the cleaning unit in a transverse direction perpendicular to the conveying direction, the base unit including a lifting guide rail, a lifting seat and a pushing module, the lifting seat being mounted on the lifting rail, being movable along the lifting rail in a top-bottom direction perpendicular to the conveying direction and the transverse direction, and being adapted for receiving the magazine, the pushing module being disposed at one side of the lifting seat opposite to the carrier unit, the carrier unit including a carrier guide rail, and a front carrier seat and a rear carrier seat that are mounted on the carrier guide rail and that are movable along the carrier guide rail in a transverse direction;
(B) operating the base unit to convey the boats sequentially from the magazine to the front carrier seat of the carrier unit, such that the boats are subsequently conveyed through the cleaning unit and the direction-changing unit into the drying unit;
(C) when any one of the boats arrives at the drying unit, driving the rear carrier seat to move in the transverse direction to be adjacent to the drying unit and to receive the one of the boats from the drying unit;
(D) driving the front carrier seat to move in the transverse direction to be adjacent to the cleaning unit, and driving the front carrier seat to execute an operation of conveying one of the boats carried by the front carrier seat to the cleaning unit;
(E′) driving the front carrier seat to move in the transverse direction to be adjacent to the base unit, and driving the base unit to execute an operation of conveying another one of the boats to the front carrier seat;
(F) driving the lifting seat and the magazine to move in the top-bottom direction along the lifting rail; and
(G′) driving the rear carrier seat to move in the transverse direction to be adjacent to the base unit, and driving the rear carrier seat to execute an operation of conveying the one of the boats carried by the rear carrier seat to the magazine.

12. The method for controlling the circulation cleaning device as claimed in claim 11, wherein step (B) includes:
(B-1) driving the lifting seat and the magazine to move in the top-bottom direction along the lifting rail such that one of the boats disposed in the magazine is aligned with the pushing module, and driving the pushing module to push the one of the boats to the front carrier seat;
(B-2) driving the front carrier seat to move in the transverse direction to be adjacent to the cleaning unit, and driving the front carrier seat to execute an operation of conveying the one of the boats to the cleaning unit;
(B-3) driving the front carrier seat to move in the transverse direction to be adjacent to the base unit, driving the lifting seat and the magazine to move in the top-bottom direction along the lifting rail such that another one of the boats is aligned with the pushing module, and driving the pushing module to push the another one of the boats to the front carrier seat; and
(B-4) repeating step (B-1), step (B-2), and step (B-3) until the drying unit receives any one of the boats.

13. The method for controlling the circulation cleaning device as claimed in claim 11, wherein in each of step (A) to step (G), the front carrier seat and the rear carrier seat are co-movable with each other.
